(19) United States
(12) Patent Application Publication
(10) Pub. No.: US 2010/0262391 A1
(43) Pub. Date: Oct. 14, 2010

(54) DEVICE FOR TESTING A PLUG-IN CONNECTION

(75) Inventor: Axel Sauermann, Helmste-Deinste (DE)

Correspondence Address: GREER, BURNS & CRAIN, 300 S WACKER DR, 25TH FLOOR, CHICAGO, IL, 60606, US

(73) Assignee: AIRBUS OPERATIONS GMBH, Hamburg (DE)

(21) Appl. No.: 12/575,814

(22) Filed: Oct. 8, 2009

Related U.S. Application Data
(60) Provisional application No. 61/111,456, filed on Nov. 5, 2008.

(51) Int. Cl. G01R 31/00

(52) U.S. Cl. 702/58

(57) ABSTRACT

The invention relates to a device for testing a connection, the connection connecting a first line to a second line.

According to the invention, a first detector and a coupling in are arranged in the region of the first line and a second detector is arranged in the region of the second line, the detectors and the coupling in being connected to an evaluation unit.

Owing to the two detectors arranged on either side of the connection to be tested and the difference between the two measuring signals of the detectors which is established in the subsequent comparator, any electromagnetic interference irradiated from outside into the lines is ideally completely removed. The device thus makes it possible to test the passage between the connected lines in a quick, reliable and precise manner. The electrical passage of connections between all types of lines, for example even between electrically conductive pipes or hoses, can be tested, even if the primary application of the device lies within the field of testing electrical connections.

Neither the lines nor the connection must be separated in order to be tested. Furthermore, all different types of lines, in particular lines having a plurality of different wires, wire combinations and/or lines of varying cross-sections, can be tested, without having to make any adjustments to and/or carry out any calibration procedures on the device specifically for this purpose.

The invention also relates to a method for testing connections between lines using the device.

### CROSS REFERENCE TO RELATED APPLICATIONS

This application claims the benefit of U.S. provisional Patent Application No. 61/111,456, filed Nov. 5, 2008, the entire disclosure of which is herein incorporated by reference.

### FIELD OF THE INVENTION

The invention relates to a device for testing a connection, the connection connecting a first line to a second line. The invention also relates to a method for testing a connection between two lines.

In modern aircraft construction, sectional construction is becoming increasingly common. Ready-made portions, such as fuselage portions, wing portions, cockpit portions and tail portions are assembled in steps in order to complete the entire aircraft. The portions are generally provided, at least in part, with the necessary technical equipment systems. These equipment systems are, for example, electrical systems, hydraulic systems, pneumatic systems, air conditioning systems as well as fresh and waste water lines. When integrating the portions to form a complete aircraft, the equipment systems must usually be interconnected within the relevant portions. The various technical equipment systems within the portions are connected by way of connectors. In the case of electrical lines, these may be, for example, plug-in, screw-in and/or clipped connectors. Hydraulic lines and pneumatic lines can also be repeatedly disconnected from one another if necessary using suitable plug-in connectors. There are also connection systems for air conditioning lines, fresh water lines and/or waste water lines, which systems may be pluggable or otherwise connectable and, if necessary, repeatedly disconnectable.

The strict conditions of aviation authorities require each line connection in an aircraft to be tested extensively, resulting in considerable cost. This cost rises owing to the ever increasing number of line connections needed for increased comfort requirements, for example when providing complex entertainment systems. Furthermore, there is the additional drawback that in many cases it is only possible to test the connection by switching on the relevant equipment systems and units, increasing testing costs further still. In addition, connection faults are often difficult to localise since contact errors are not always reliably reproduced. For example, electrical contact pins within a plug-in connection may be pushed back in an undefined manner when the connection is closed, breaking the connection, and then pulled back into the starting position when the connection is subsequently released again. Connection errors of this type cannot be localised during visual examination of the connection elements. Dirt and foreign particles may also lead to contact faults caused by changes in humidity, pressure and/or current strength and may produce leakage current.

Incidentally, the generally rather small amount of space available, particularly in the connection region of the wings and the elevator unit, hinders testing of the plug-in connectors using conventional methods.

### SUMMARY OF THE INVENTION

The object of the invention is thus to provide a device for testing line connections, in particular electrical line connections, which makes it possible to test a connection which has already been closed between two lines, in particular two electrical lines, in a simple, quick and reliable manner, irrespective of the number of wires in the lines and their cross-sections.

This object is achieved by a device having the features of claim 1.

Since a first detector and a coupling in are arranged in the region of the first line and a second detector is arranged in the region of the second line, the detectors and the coupling in being connected to an evaluation unit, it is possible to detect connection faults in the region of a connection between two lines in a reliable, quick and safe manner irrespective of the type of line. Of course, the device according to the invention may also be used to test connections between hydraulic lines, pneumatic lines and other types of line, provided the connection site and the lines connected thereto are sufficiently electrically conductive. However, the main field of application of the device is detecting possible connection faults or contact faults in the region of a connector or plug-in, clipped or screw-in connection between two electrical lines. In this regard, in addition to pure contact faults within the connector, line faults, such as cable breaks, wire breaks, reduced cross-sections caused by wire breaks, etc within the lines to be tested can also be localised in the region between the two detectors.

A first detector and the coupling in for a reference signal are arranged in the region of the first line, i.e. to the left-hand side of the connection. The coupling in is thus arranged in the region between the first detector and the electrical connection. The second detector is arranged in the region of the second line, i.e. generally on the side of the connection remote from the first detector. Alternatively, the first detector and the coupling in as well as the second detector may also be arranged in a mirror-inverted manner relative to the connection. The coupling in of the differential signal and the coupling out of the two measuring signals are preferably achieved inductively, but alternatively may also be achieved galvanically. However, galvanic coupling in or coupling out poses the drawback that there is no separation of potential between the device and the electrical system of the aircraft. Furthermore, galvanic coupling in is generally detrimental to the mechanical integrity of the electrical insulation of the lines. However, very small D.C. currents can be fed using galvanic coupling in, it being possible to prevent any damage to sensitive electronic circuits which are connected to the lines.

According to an advantageous embodiment, the two lines are, in particular, electrical bunched cables comprising a plurality of wires and the connector is an electrical plug-in and/or clipped connector.

By way of the device, not only is it possible to test a connection between two single-wire electrical lines, but it is also possible to test a connection between two bunched cables comprising any number of wires and/or of different line cross-sections in just a single test step. However, what are known as ‘twisted pair’ lines cannot be tested using the device, since no currents can be induced into these types of lines through the coupling in. This type of line is used, for example, in LAN connection cables. The currents or voltages induced through outer magnetic fields are compensated by the twisted pair cables in such a way that continuous data transfer, which is not susceptible to interference, is enabled. Electrical lines which have a shield, for example coaxial cables, can also not be tested.

According to a further advantageous embodiment of the invention, the coupling in is connected to a signal generator.

The signal generator, which is electrically connected to the coupling in, makes it possible to feed a preferably time-variable reference signal into the first line, it also being possible to alter the course of the reference signal, i.e. the signal shape of the reference signal over time and the frequency within wide ranges. The signal generator generates any reference signal so the device can easily be adapted to a wide range of requirements, for example the impedance of the lines to be tested. For example, a sinusoidal, rectangular, triangular or sawtooth-shaped reference signal may be generated. Furthermore, depending on the type of line to be tested, harmonic signal shapes or noise signals may also be fed into the first line via the coupling in.

According to the features of a further advantageous embodiment, it is provided for the two detectors to be connected to a comparator for generating a differential signal, the differential signal having a value close to zero when the connection is intact.

Owing to this differential measurement, contact faults in the region of the connection between the two electrical lines and/or electrical faults inside the lines can easily be detected in a reliable manner. As a result of the differential method used, the signal shape of the reference signal fed into the first line is not generally significant. When assessing the differential signal, it must be assumed that even minor deviations from the value of zero still indicate that the connection is intact and the electrical lines are in perfect condition, in order to prevent any indication errors. For this purpose, the comparator should be provided with an adjustable hysteresis threshold.

It may also be necessary to invert the output signal of one of the two detectors, i.e. to carry out a sign reversal. Furthermore, the provision of a closed circuit is necessary in order to effect a current flow I in the connected lines via the preferably inductive coupling in of the reference signal, which current flow can be measured by the detectors. The circuit formed by the two connected lines may be closed, for example by separate return lines and/or ground loops.

According to the features of a further advantageous development, the comparator is connected to an output unit, in particular to a display unit. A clear visualisation of the measurement result can thus be provided in the form of the differential signal. Generally, it is necessary to process the differential signal in a comprehensive electronic and mathematical manner in order to obtain a perfect and, above all, reproducible test result. LED displays, seven-segment displays, dot matrix displays, alphanumeric displays or LCD displays and LCD colour displays may be used as a display unit. Alternatively, the test result may be signalled in an acoustic manner. In this case, the quality of the connection or of the lines connected on either side to the connector may be coded, for example by way of a graded scale.

A further development of the device provides for a computer unit for evaluating the differential signal to be arranged between the comparator and the output unit.

The computer unit comprehensively processes the analogue differential signal generated by the comparator. The generally analogue differential signal generated by the comparator is not only processed numerically inside the computer unit, but is also comprehensively processed from a metrological point of view. For example, the differential signal of the comparator is first amplified, filtered and then preferably digitalised in a highly accurate manner using a fast analog-to-digital converter. The digitalised differential signal is then comprehensively mathematically processed using suitable algorithms in order to produce clear and reliable test results. The definitive test signal thus produced from the differential signal is then displayed in the output unit, for example in the form of an LCD colour display.

Further advantageous embodiments of the device are disclosed in subsequent claims.

In addition, the object according to the invention is solved by a method according to the features of claim 10 and comprising the following method steps:
a) feeding a reference signal into the first line by way of the coupling in,
b) supplying the measuring signals generated by the two detectors to a comparator, and
c) outputting a differential signal, generated by the comparator from the two measuring signals, to an output unit.

In method step a), a reference signal suitable for the line combination to be tested is fed into the first line via the coupling in on the left-hand side of the connection. Alternatively, the signal may also be coupled in from the right-hand side of the line connection. In subsequent method step b), the measuring signals detected by the two detectors are directed to a comparator so as to produce the desired differential signal. Lastly, in method step c), the (analogue) differential signal produced by the comparator from the two measuring signals is output at a suitable output unit in order to visualise the test result.

In particular, the method according to the invention poses the advantage that the test result for the quality of the line connection is obtained from the differential signal alone, so the qualitative shape and size of the fed reference signal is generally not important and interfering electromagnetic irradiation can also usually be mutually compensated in the region of the line connections.

Furthermore, line combinations can also be tested in a safe and inexpensive manner, entirely irrespective of the line cross-sections used, the type of lines and/or the number of wires in the respective lines using the method according to the invention. In order to carry out a test, the device must not generally be pre-set with regard to the type of line to be tested. In addition, the preferably inductive coupling in of the differential signal and the likewise preferred inductive coupling out of the measuring signals also pose the advantage that the lines or connection between the lines to be tested do not have to be separated in order to be tested. Furthermore, the inductive coupling in completely galvanically separates line systems to be tested from the device in such a way that the use of ground loops, which may lead to measurement errors, can be avoided.

Further advantageous embodiments of the method are disclosed in the other claims.

### BRIEF DESCRIPTION OF THE DRAWINGS

In the drawings:

FIG. 1 is a block diagram of the device according to the invention,

FIG. 2 shows a first variant of a detector, and

FIG. 3 shows a second variant of a detector.

### DESCRIPTION OF EXEMPLARY EMBODIMENTS

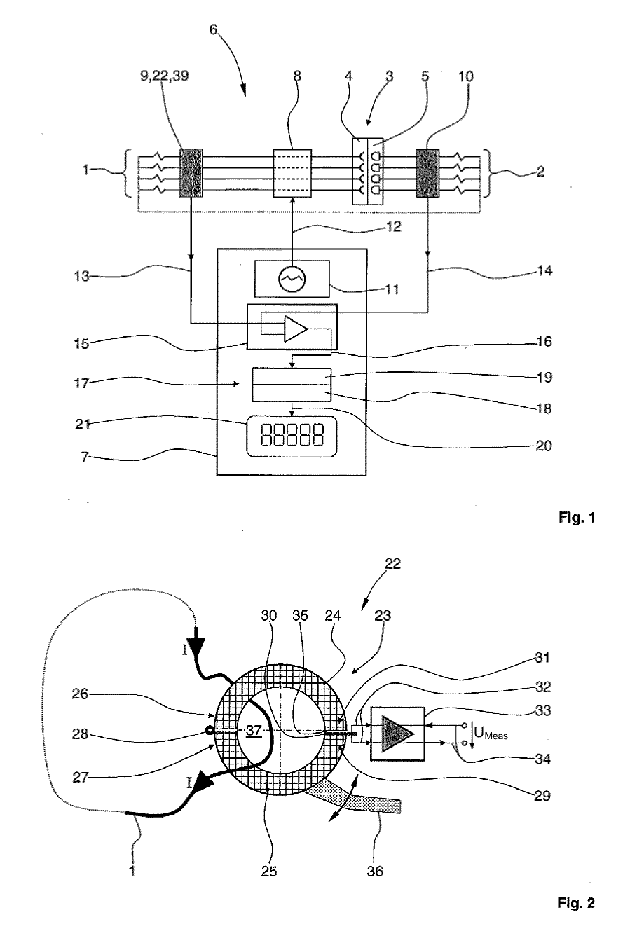

FIG. 1 shows a rather simplified block diagram of the device with two lines which are connected by a connector.

Two cables or two electrical lines 1, 2, each comprising four wires (not referenced) are connected to one another by a connector 3. The connector 3 comprises a socket 4 and a plug 5, in each of which respectively four plug sockets and plug pins (not provided with a reference numeral) are integrated. The electrical connection between the lines 1, 2 is achieved by plugging the plug pins into the respective plug sockets of the connector 3. Generally, the connector 3 comprises up to a hundred plug pins and sockets. Connectors 3 between any type of lines 1, 2, for example even electrical pipes or hoses, can be tested for a sufficient electrical passage using the device, even if the main application of the device 6 is viewed as lying within the field of testing an electrically perfect contact in a (plug-in) connector.

A device 6 configured in accordance with the invention comprises, inter alia, an evaluation unit 7, a coupling in 8 and a first and second detector 9, 10.

The detectors 9, 10 are preferably configured as resiliently hinged pincers, so it is not necessary to release the connector 3 in order to position the detectors 9, 10 on the lines 1, 2 so as to test said lines.

A signal generator 11 integrated in the evaluation unit 7 generates a reference signal 12 which is inductively coupled in via the coupling in 8 into the line 1 arranged on the left-hand side of the connector 3. Of course, the coupling in 8 may also be arranged on the right-hand side of the connector 3 on the second line 2 before the second detector.

The two ends (not provided with a reference numeral) of the lines 1, 2 or of the cables are connected via at least one return line or a common ground loop (indicated by a dotted line) to form a closed circuit so as to enable a current flow I in the lines 1, 2 owing to the preferably inductive coupling in of the differential signal through the coupling in 8. The magnetic field produced by said current I may be evaluated by the detectors 9, 10.

Two measuring signals 13, 14 are removed from the lines 1,2 by way of the two detectors 9, 10, in particular they are inductively coupled out, and fed to a comparator 15. A preamplifier (not shown) may be provided between the detectors 9, 10 and the two inputs of the comparator 15, which preamplifier is used, in particular, to filter, preamplify, zero shift and further process (from a metrological point of view) the measuring signals 13, 14 generated by the detectors 9, 10. In order to reduce the influence of external interference signals, the reference signal 12 generated by the signal generator 11 may be modulated so it is possible for the modulated signal to be processed merely selectively from a metrological point of view, i.e. filtered and amplified in the preamplifier so as to effectively eliminate any undesired coupling in interference. In an arrangement of this type, the preamplifier is fitted with at least one so-called ‘chopper’ amplifier. In accordance with the configuration of the aforementioned optional preamplifier for the measuring signals of the detectors 9, 10, ‘chopper’ circuitry may also be used in the comparator 15 to effectively eliminate interference.

A differential signal 16 is obtained in the comparator 15 from the two measuring signals 13, 14, which differential signal is fed to a computer unit 17. The computer unit 17 comprises an analog portion 18 and a digital portion 19. The generally analog differential signal 16 produced by the comparator 15 is filtered, amplified and optionally offset shifted in the analog portion 18. The analog differential signal 16 processed from a metrological point of view is digitalised in the digital portion 19 by a fast analog-to-digital converter in real time and the differential signal 16 now in digital form is mathematically processed further by using suitable mathematical algorithms. The digitalised differential signal 16 is mathematically processed, for example, by fast signal processors or standard processors in real time. An output signal 20, which ultimately represents the desired test result and is produced from the differential signal 16 in the digital portion 19 of the evaluation unit 7, is subsequently fed to an output unit 21 which visualises the result. In the embodiment shown, the output unit is configured as a conventional five-digit, seven-segment LED digital display. In order to be able to visualise more information using the output unit 21, said unit is preferably a high-resolution colour LCD monitor.

So as to be able to operate and handle the device easily in small installation spaces without being able to see the testing device, the output signal may also be acoustically encoded. For example, the quality of the electrical connection may be indicated by way of differently scaled sounds. In this case, a high-pitched sound on the scale would indicate an optimal electrical connection, whilst in contrast a lower pitch would indicate connection faults. Of course, quantitative test results could also be encoded using acoustic signalling. In an arrangement of this type, the tone pitch is proportional to current-flow resistance, digitalisation being achieved by a plurality of pitches.

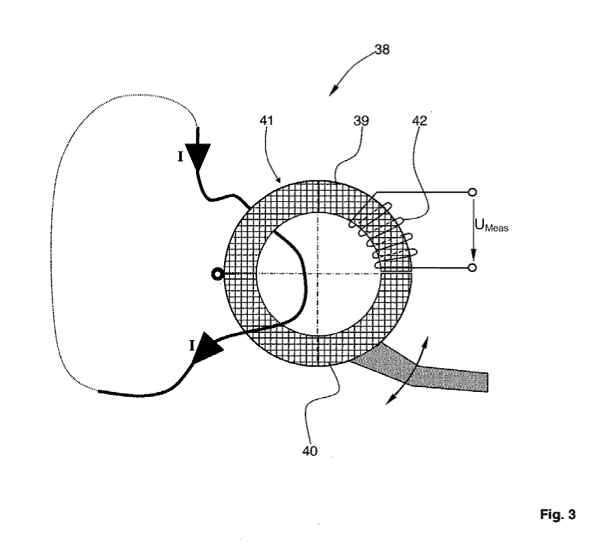

FIG. 2 shows a first embodiment of a detector in the closed state.

A detector 22 is basically formed with a torus 23 comprising, for example, an annular or polygonal cross-section geometry, the torus 23 being formed using a highly conductive, magnetic material. In the embodiment shown, the torus 23 has an upper and lower semi-circular branch 24, 25, the rear ends 26, 27 of which are connected to one another via a hinged joint 28. The hinged joint 28 has a torsion spring (not shown) so as to enable, inter alia, the semi-circular branches 24, 25 to close automatically. A Hall sensor 30 is fixed, for example, to a front end 29 of the lower branch 25. A front end 31 of the upper branch 24 ideally completely abuts the Hall sensor 30 but can easily be removed from said sensor. Owing to the resilience of the torsion spring integrated into the hinged joint 28, the front end 31 of the upper branch 24 is pressed against the Hall sensor 30 with a defined and, if necessary, adjustable pressure. The Hall sensor 30 is firstly connected to a highly sensitive preamplifier 33, for example an electrometer amplifier or the like, via a measuring line 32. The measuring signal preamplified in the preamplifier 33 is fed (optionally by way of further intermediate steps) via a further measuring line 34 to the comparator 15. The measuring voltage U_{Meas} to be evaluated by the comparator 15 decreases over the measuring line.

A narrow gap 35 shown in FIG. 2 between the front ends 29, 31 of the branches 24, 25 merely clarifies, in an illustrative manner, that the branches 24, 25 can be rotated away from one another by a user by way of a hand lever 36 so as to completely surround a line to be tested. During the practical measuring process, the gap 35 is always completely closed by the spring action of the torsion spring. In the closed state of the torus 23, the two closed branches 24, 25 of said torus form a closed magnetic circle having low magnetic resistance, which circle completely surrounds the line 1 to be tested using the device 6, i.e. the line 1 extends through an opening 37 of the torus 23. The branches 24, 25 which may be folded apart pose the particular advantage that the line 1 to be tested does not have to be separated in order to be tested.

By way of the Hall sensor 30, the magnetic flux density or the magnetic field strength in the torus 23 can be measured, this in turn being a measure of the reference signal 12 generated in the line 1 by the signal generator 11 or the current I generated in the line 1 by the reference signal 12. By using the Hall sensor 30, both alternating currents and direct currents can be detected in the line 1. The torus 23 and the branches 24, 25 which may be folded together to form said torus are made of a material having low magnetic resistance so as to obtain the greatest field strength possible in the region of the Hall sensor 30.

The dotted line indicates a return line for closing the circuit so as to enable the current flow I. This return line may also be present in the form of an ground loop for example.

FIG. 3 shows a second embodiment of a detector, the mechanical construction of which corresponds with that of the detector 22 in accordance with the features of FIG. 2 in such a way that, with regard to the details of this mechanical construction, reference is made to the explanations already given with regard to FIG. 2.

A detector 38 also comprises an upper and a lower branch 39, 40 (also semi-circular) which form a torus 41 having any desired cross-section geometry and completely surrounding the line 1 to be tested. A return line which is necessary for the current flow I is in turn indicated by a dotted line.

Instead of a Hall sensor 30, the embodiment of this detector 38 is provided with a winding 42 on the upper branch 39, which winding forms an approximately cylindrical coil. The alternating current I flowing through the line 1 induces a measuring voltage U_{Meas} of low amplitude into the winding 42, which voltage is in turn forwarded to the comparator 15 of the device 6 for evaluation. The alternating current I is generated by the reference signal 12 produced by the signal generator 11, which leads to a decrease in voltage along the line 1 to be tested and along the connector 3. This variant poses the advantage of a simple construction but does, however, pose the drawback that an alternating current I must flow through the line 1 in order to be able to inductively generate the measuring voltage U_{Meas}.

The requirement of an alternating current flow may, however, in some circumstances lead to problems in sensitive electronic circuits which are connected to the line 1.

### LIST OF REFERENCE NUMERALS

1 first line (cable)
2 second line (cable)
3 connector
4 socket
5 plug pin
6 device
7 evaluation unit
8 coupling in
9 first detector
10 second detector
11 signal generator
12 reference signal
13 measuring signal (first detector)
14 measuring signal (second detector)
15 comparator
16 differential signal
17 computer unit
18 analog portion
19 digital portion
20 output signal
21 output unit
22 detector
23 torus
24 upper branch
25 lower branch
26 rear end (upper branch)
27 rear end (lower branch)
28 hinged joint
29 front end (lower branch)
30 Hall sensor
31 front end (upper branch)
32 measuring line
33 preamplifier
34 measuring line
35 gap
36 hand lever
37 opening
38 detector
39 upper branch
40 lower branch
41 torus
42 winding

1. A device for testing a connection, the connection connecting a first line to a second line, characterised in that a first detector and a coupling in are arranged in the region of the first line and a second detector is arranged in the region of the second line, the detectors and the coupling in being connected to an evaluation unit.

2. The device according to claim 1, wherein the two lines are, in particular, electrical bunched cables comprising a plurality of wires and the connection is configured as an electrical plug-in and/or clipped connection.

3. The device according to claim 1, wherein the coupling in is connected to a signal generator.

4. The device according to claim 1, wherein the two detectors are connected to a comparator for generating a differential signal and the differential signal has a value close to zero when the connection is intact.

5. The device according to claim 4, wherein the comparator is connected to an output unit, in particular to a display unit.

6. The device according to claim 5, wherein a computer unit for evaluating the differential signal is arranged between the comparator and the output unit.

7. The device according to claim 3, wherein a reference signal generated by the signal generator is inductively coupled into the first line.

8. The device according to claim 1, wherein measuring signals of the detectors are generated by a winding, in particular a coil, and/or by a Hall sensor.

9. The device according to claim 6, wherein the at least one signal generator, the comparator, the computer unit and the output unit are portably comprised within the evaluation unit.

10. A method for testing a connection between a first and second line, in particular by way of a device according to claim 1, wherein a first detector and a coupling in are arranged in the region of the first line and a second detector is arranged in the region of the second line, comprising the following steps:
a) feeding a reference signal into the first line by way of the coupling in,
b) supplying the measuring signals generated by the two detectors to a comparator, and
c) outputting a differential signal, generated by the comparator from the two measuring signals, to an output unit.

11. The method according to claim 10, wherein the differential signal is evaluated in a computer unit arranged downstream of the comparator and is subsequently transferred to the output unit.

12. The method according to claim 10, wherein a differential signal having a value close to zero indicates that the connection is intact.
